(19) United States
(12) Patent Application Publication
(10) Pub. No.: US 2013/0070510 A1
(43) Pub. Date: Mar. 21, 2013

(54) METHOD FOR READING A HOLOGRAPHIC MEMORY ON A DATA MEDIUM

(71) Applicants: Frances Allot, Marseille (FR); Antoine Bajolle, Auriol (FR); Sabastien Gaspari, Marseille (FR)

(72) Inventors: Frances Allot, Marseille (FR); Antoine Bajolle, Auriol (FR); Sabastien Gaspari, Marseille (FR)

(73) Assignee: GEMALTO SA, Meudon (FR)

(21) Appl. No.: 13/701,390

(22) PCT Filed: May 30, 2011
(86) PCT No.: PCT/EP11/58842

§ 371 Date: Nov. 30, 2012

(30) Foreign Application Priority Data
May 31, 2010 (EP) 10305570.3

(51) Int. Cl. G03H 1/02; G11C 13/04

(52) U.S. Cl. CPC G03H 1/02; G11C 13/04
USPC 365/125; 359/3

(57) ABSTRACT

The embodiments of this invention also describe to a data medium comprising
a holographic memory carried on the medium, and
a photonic crystal configured, firstly, to filter the light received from a broad-spectrum light source in order to select a frequency band of the said spectrum and secondly, to guide the light corresponding to the said selected frequency band so as to light the said holographic memory in a predefined direction.

This invention relates to the area of optical memories and more particularly memories using a holographic method and the methods for reading such memories.

By recording the interference patterns derived from the superposition of a coherent reference beam and the same beam diffracted by an object (which is the information to record), an image (hologram) is recorded comprising information in three dimensions, because the totality of the wave front of the beam received (amplitude, wavelength and phase) is recorded. In that way, numerous pieces of information can be recorded on a small surface. The image of the object (and therefore the data) can be recreated by lighting the interference patterns (that is to say the hologram) with the reference beam. That is how holography makes it possible to design memories with large capacities.

However, in order to recreate the original image from the recording of interference patterns, the holographic memory must be lit in very particular conditions: a reading angle with low deviation and a specific wavelength in order to remain in coherent light conditions.

But the fulfillment of these lighting conditions is difficult, and the reading of holographic memories in the state of the art requires a reading device that is very complex and very sensitive to the outside environment, making the use of such memories very difficult for the general public.

There is thus a need to offer a reading method that makes it possible to access the data in the holographic memory simply and speedily.

Therefore, this invention relates to a data medium comprising

a holographic memory carried on the medium, and

a photonic crystal configured, firstly, to filter the light received from a broad-spectrum light source in order to select a frequency band of the said spectrum and secondly, to guide the light corresponding to the said selected frequency band so as to light the said holographic memory in a predefined direction.

In another aspect of this invention, the photonic crystal comprises a prohibited band wherein the wavelengths located in the said prohibited band are reflected so as to create a waveguide for those wavelengths.

In an additional aspect of this invention, the photonic crystal comprises an optical resonator that makes it possible to light the holographic memory coherently with the light spectrum corresponding with the selected frequency band.

In another embodiment of this invention, the format of the said medium is a memory card that allows the easy handling of the said data medium.

In an additional embodiment of this invention, the memory card comprises a window that makes it possible to transmit the broad-spectrum light received to the photonic crystal and wherein the said window and the holographic memory are positioned on the same side of the memory card.

In an alternative embodiment, the memory card comprises a window that makes it possible to transmit the broad-spectrum light received to the photonic crystal and wherein the said window and the holographic memory are positioned on opposite sides of the memory card.

This invention also relates to equipment for reading a data medium according to any of the foregoing claims comprising:

a broad-spectrum light source designed to emit to the photonic crystal of the data medium,

an optical sensor designed to detect the image created by lighting the holographic memory,

a signal processing module designed to process the signal detected by the optical sensor in order to recover the data recorded in the holographic memory.

According to another aspect of this invention, the broad-spectrum light source is a source of white light.

According to a supplementary aspect of this invention, the said optical sensor is a charge-coupled device (CCD) optical sensor.

According to an additional aspect of this invention, the said optical sensor is a complementary metal oxide semiconductor (CMOS) optical sensor.

This invention also relates to a method of reading a holographic memory in which the structure of a photonic crystal is configured, firstly, to filter the light received from a broad-spectrum light source in order to select a frequency band of the said spectrum and secondly, to guide the light corresponding to the said selected frequency band so as to light the holographic memory in a predefined direction.

According to another aspect of this invention, the photonic crystal and the holographic memory are implemented on a card and wherein the broad-spectrum light source and the optical sensor are fixed in reading equipment on which the said card is inserted.

Other characteristics and advantages of the invention will appear in the description below, by reference to the attached drawings, which illustrate a possible embodiment, for information and in a non-limitative manner.

In these drawings:

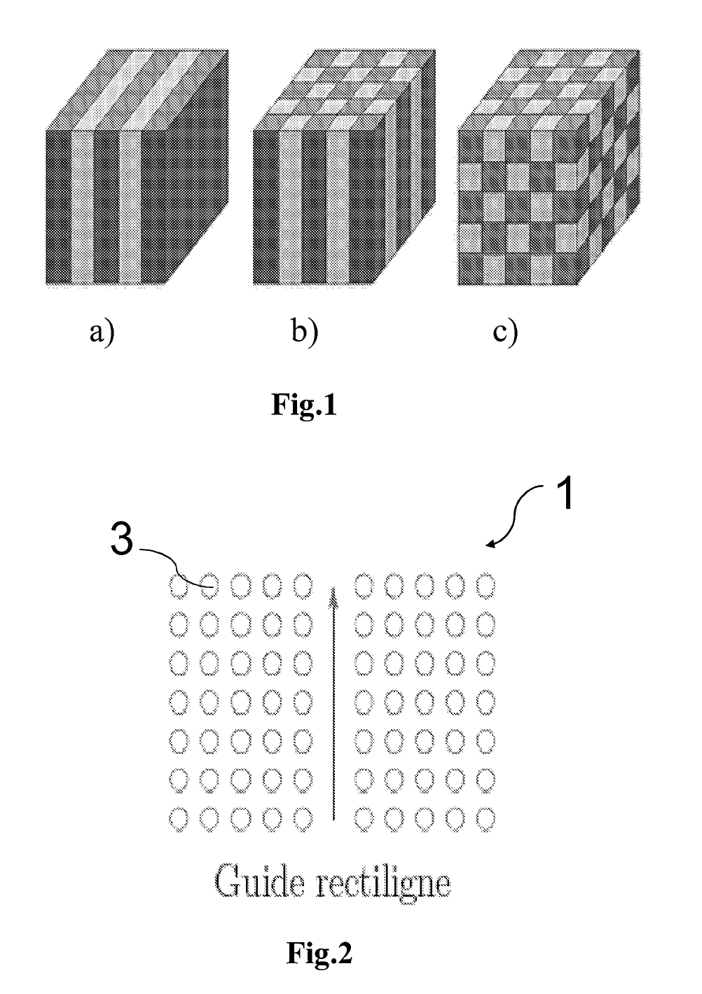

FIG. 1 represents a diagram of three photonic crystals in one (a)), two (b)) and three (c)) dimensions;

FIG. 2 represents a diagram of a rectilinear defect in a photonic crystal corresponding with the formation of a rectilinear waveguide;

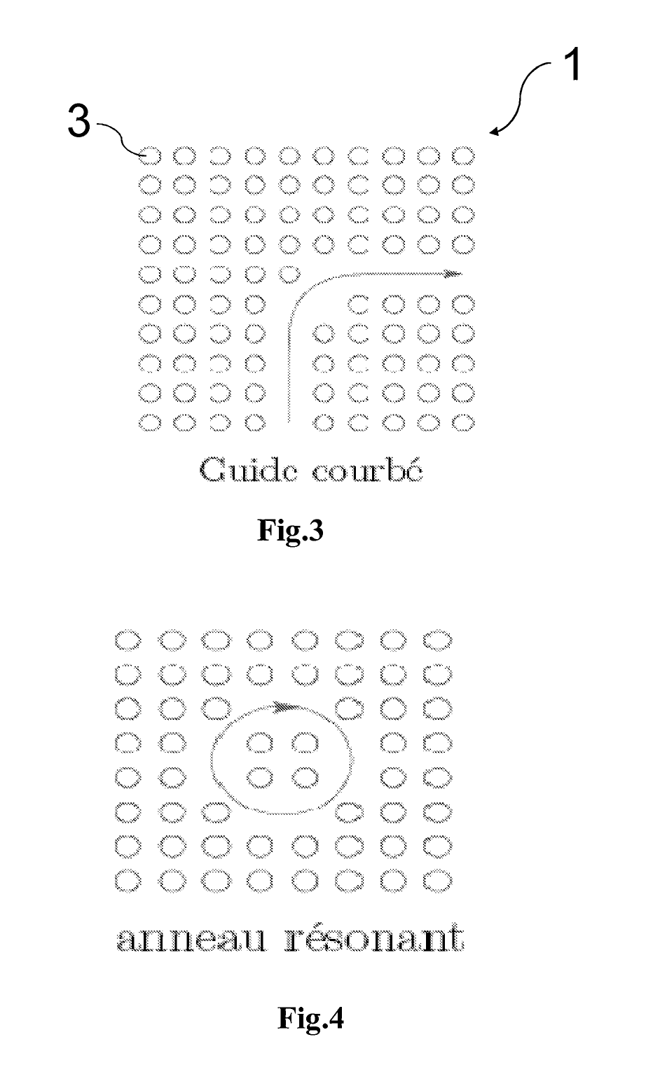

FIG. 3 represents a diagram of a curved defect in a photonic crystal corresponding with the formation of a curved waveguide;

FIG. 4 represents a diagram of an annular defect in a photonic crystal corresponding with the formation of an optical resonator;

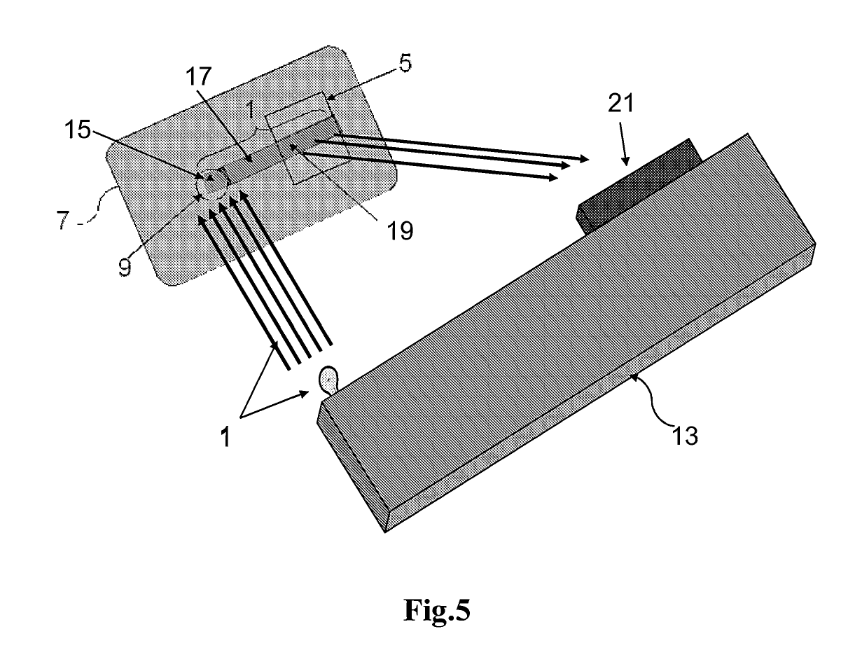

FIG. 5 represents the explanatory diagram of the working of the embodiments of this invention;

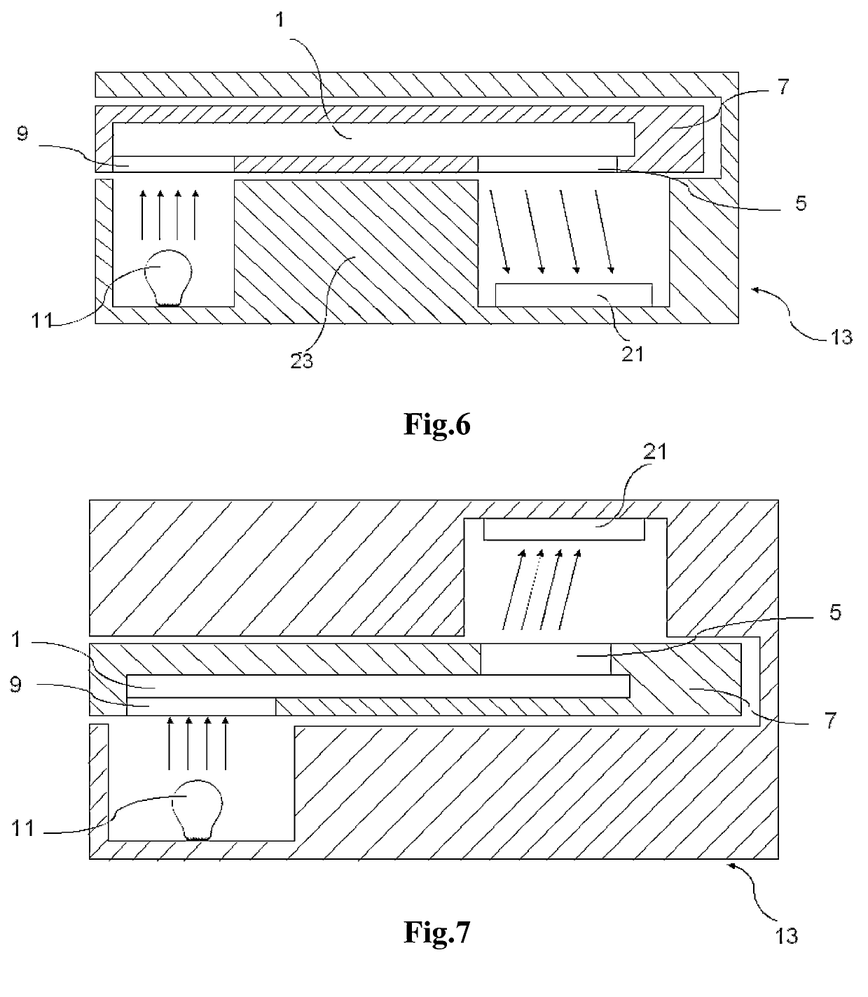

FIG. 6 represents a first embodiment of this invention;

FIG. 7 represents a second embodiment of this invention;

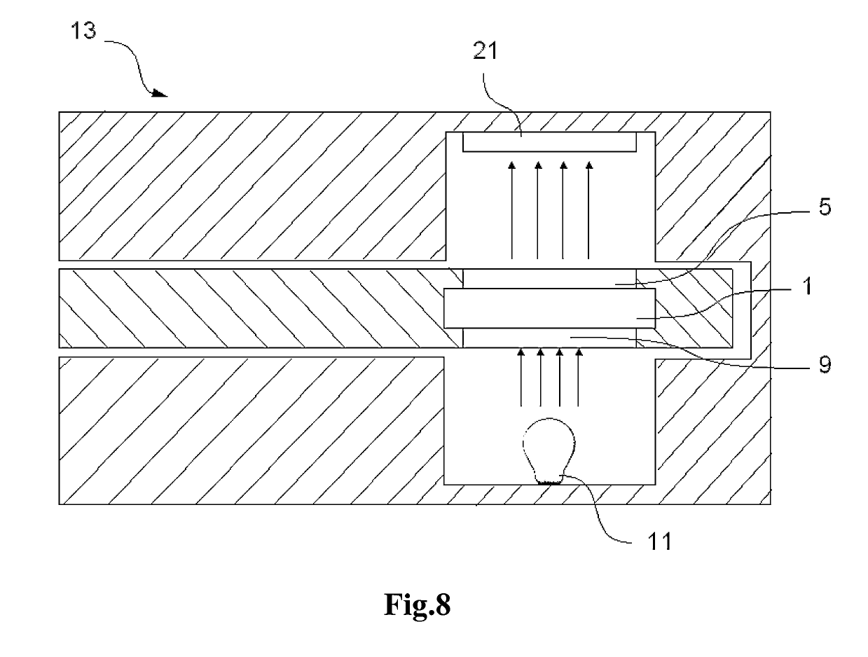

FIG. 8 represents a third embodiment of this invention;

In the description below, the following are generally designated:

The term “broad-spectrum light source” defines a light source where the spectral range includes the wavelength required for lighting a holographic memory, and also other wavelengths, so that filtering is required to obtain that wavelength.

The embodiments of this invention relate to the use of a photonic crystal in order to filter and guide the spectrum derived from white light.

A photonic crystal is a periodic structure of dielectric materials with different refraction coefficients. The periodic arrangement and the difference in the refraction coefficients of the two materials leads to the formation of a “photonic prohibited band” in which the wavelengths are reflected. By selecting the difference in refraction coefficients and working on the periodicity of the arrangement (type of network, hole diameter) or by adding local defects (absence, modification or displacement of patterns), it is possible to tune the photonic inhibited band for the needs of the application. If that prohibited band is fine enough, that leads to the formation of a waveguide that transmits the wavelengths included in the band. Thus, the configuration of the photonic crystal makes it possible to select the spectral band to be transmitted.

Further, as shown in FIG. 1, there are photonic crystals with one (a)), two (b)) and three (c)) dimensions. In the case of a two-dimensional crystal, it is generally made up of a network of holes made in dielectric material or columns of dielectrics in air. In both cases, the introduction of a local defect (no hole or column) leads to the containment of the electromagnetic mode whose energy is located in the prohibited band of the photonic crystal located around it. That amounts to the creation of a cavity at the corresponding wavelength, which wavelength varies depending on the size (radius) of the defect. The containment makes it possible to create an intense light source with a small spectral range.

Similarly, by creating invariant extended defects by displacement (that is very great before the wavelength) in at least one dimension, the propagation of the light can be directed and waveguides can be created in a selected direction as represented in FIG. 2.

Curved waveguides can also be obtained as represented in FIG. 3.

Lastly, an optical resonator configuration (FIG. 4) makes it possible to emit the spectrum transmitted by the photonic crystal in the form of coherent light. Such an “optical function” is the making of defect mode photonic crystal lasers (optical cavity formed by a local defect in a photonic crystal) or band edge photonic crystal lasers.

It must be noted that the making of photonic crystals such as those described above to allow filtering, guiding and received light emission functions is known in the state of the art (Joannopoulos (J. D.), Meade (R. D.) and Winn (J. N.), “Photonic Crystals: Molding the Flow of Light”. Princeton University Press, 1995; Romuald Houdré, “Cours de l'ecole doctorale de photonique, EDPO PO-014 2009”, EPFL, 2009; Josselin Mouette, “Micro-résonateurs sans cavités à base de cristaux photoniques bidimensionnels”, rapport stage DEA, 2001).

Besides, it must be noted that this invention relates to the reading of holographic memories but not writing, which also requires very specific conditions (coherent light etc.).

In one embodiment, the photonic crystal 1 and the holographic memory 5 are located on a common card 7 so as to facilitate the handling of the holographic memory 5 and to fix the holographic crystal 1 in the configuration and the position required in relation to the holographic memory 5.

The card 7 also comprises a transparent window 9 in order to receive a broad-spectrum beam 11 emitted by a reading device 13. That broad-spectrum beam 11 transmitted through the transparent window 9 is then received by a first part 15 of the photonic crystal 1 which is configured to filter the broad-spectrum beam 11 received so as to select the spectral band required to light the holographic memory 5. The filtered spectral band is then transmitted to the holographic memory 5 by a second part 17 of the photonic crystal 1 including a waveguide configuration as described above. In practice, the photonic crystal is made up of a single block with different hole arrangements to obtain the required light signal to light the holographic memory; further, the filtering and guiding functions are carried out by a unique waveguide arrangement because as described above, only the wavelengths of the prohibited band are transmitted by the waveguide.

Lastly, the selected spectral band is received by a third part 19 of the photonic crystal 1 which is configured as an optical resonator to allow the radiation of a selected spectrum to the holographic memory 5 at the required angle. Thus, the photonic crystal is configured so that the incident angle and the spectral width obtained match the reference beam used while writing the holographic memory.

The image formed by lighting the holographic memory 5 is then analysed by an optical detector 21 located on the reading device 13.

FIG. 5 is an explanatory diagram that details the working of the invention.

In practice, in the embodiments of this invention, the card 7 is fixed to the reading device 13 so that it is positioned to make it possible to light the transparent window 9 with the broad-spectrum light source 11 and then form the image of the holographic memory 5 at the optical sensor 21.

The broad-spectrum light source 11 may, for example, be an incandescent lamp or a light-emitting diode, so that its spectral range is variably large, where what matters is that the spectrum of the light source comprises the wavelength required for lighting the holographic memory 5.

The optical sensor 21 may be a charge-coupled device (CCD) or a complementary metal oxide semiconductor (CMOS) optical sensor. Besides, the signal from the optical sensor is analysed by the electronic signal processing module in order to convert the information contained in the holographic memory to the required format.

Different configurations are possible to allow the reading of a holographic memory according to the working described above.

In a first embodiment presented in FIG. 6, once the card is inserted in the reader, it is lit by a broad-spectrum light source 11 at its window 9. The light is then filtered and guided by the photonic crystal 1 and then diffused by the same crystal 1 to the holographic memory 5. The light rays are then diffracted to the sensor 21 located on the same side of the memory card 7 as the broad-spectrum light. In that configuration, the protuberance 23 of the reader 13 makes it possible firstly to hold the card 7 in position and secondly to avoid the radiation of the broad-spectrum light 11 to the sensor 21, which could disturb the reading of the holographic memory 5. The arrows represent the transmission of light in the air, that is between the broad-spectrum light source 11 and the window 9 of the memory card 7 on one side and between the holographic memory 5 and the optical sensor 21 on the other side.

In a second embodiment presented in FIG. 7, the broad-spectrum light source 11 and the optical sensor 21 are on each side of the memory card when the card is inserted in the reader. Such a configuration makes it possible to avoid any disturbance in reading by the sensor 21 due to the light source 11.

Lastly, in a third embodiment presented in FIG. 8, the window 9, the photonic crystal 1 and the holographic memory 5 are concentrated on the thickness of the card, so that the light source 11 and the optical sensor 21 are placed symmetrically on two sides of the card, which makes it possible to reduce the size of the memory card 7.

Thus, this invention makes it possible, thanks to the use of the properties of photonic crystals, to design a method for reading holographic memories that is fast and has a limited cost, due to the absence of a coherent light source. Further, implementation of a card facilitates the handling of the holographic memory and the use of crystal photonics simplifies reading. Besides, the use of a holographic memory installed on a card makes for great ruggedness, since even if the holographic memory is broken, all the data can be recovered with only a fraction of the holographic memory.

1. A data medium comprising
a holographic memory (5) carried by the medium and,
a photonic crystal (1) configured, firstly, to filter the light received from a broad-spectrum light source (11) in order to select a frequency band of the said spectrum and secondly, to guide the light corresponding to the said selected frequency band so as to light the said holographic memory (5) in a predefined direction.

2. A data medium according to claim 1 wherein the photonic crystal (1) comprises a prohibited band wherein the wavelengths located in the said prohibited band are reflected so as to create a waveguide for those wavelengths.

3. A data medium according to claim 1 or 2, wherein the photonic crystal (1) comprises an optical resonator that makes it possible to light the holographic memory (5) coherently with the light spectrum corresponding with the selected frequency band.

4. A data medium according to claim 1 or 2, wherein the format of the said medium is a memory card (7) that allows the easy handling of the said data medium.

5. A data medium according to claim 4, wherein the memory card (7) comprises a window (9) that makes it possible to transmit the broad-spectrum light received to the photonic crystal (1) and in which the said window (9) and the holographic memory (5) are positioned on the same side of the memory card (7).

6. A data medium according to claim 4, wherein the memory card (7) comprises a window (9) that makes it possible to transmit the broad-spectrum light received to the photonic crystal (1) and in which the said window (9) and the holographic memory (5) are positioned on opposite sides of the memory card (7).

7. Reading equipment (13) for reading a data medium having a holographic memory (5) carried by the medium and, a photonic crystal (1) configured, firstly, to filter the light received from a broad-spectrum light source (11) in order to select a frequency band of the said spectrum and secondly, to guide the light corresponding to the said selected frequency band so as to light the said holographic memory (5) in a predefined direction, the equipment comprising:
a broad-spectrum light source (11) designed to emit to the photonic crystal (1) of the data medium,
an optical sensor (21) designed to detect the image created by lighting the holographic memory (5),
a signal processing module designed to process the signal detected by the optical sensor (21) in order to recover the data recorded in the holographic memory (5).

8. The reading equipment according to claim 7, wherein the broad-spectrum light source (11) is a source of white light.

9. The reading equipment according to claim 7 or 8, wherein the said optical sensor (21) is a charge-coupled device (CCD) optical sensor.

10. The reading Reading equipment according to claim 7 or 8, wherein the said optical sensor (21) is a complementary metal oxide semiconductor (CMOS) optical sensor.

11. A method of reading a holographic memory (5) wherein the structure of a photonic crystal (1) is configured, firstly, to filter the light received from a broad-spectrum light source (11) in order to select a frequency band of the said spectrum and secondly, to guide the light corresponding to the said selected frequency band so as to light the holographic memory (5) in a predefined direction.

12. The method according to claim 11 wherein the photonic crystal (1) and the holographic memory (5) are implemented on a card (7) and in which the broad-spectrum light source (11) and the optical sensor (21) are fixed in reading equipment (13) on which the said card is inserted (7).
